(19) United States
(12) Patent Application Publication
(10) Pub. No.: US 2012/0080209 A1
(43) Pub. Date: Apr. 5, 2012

(54) SHIELDING FOR COMMUNICATION CABLES USING CONDUCTIVE PARTICLES

(75) Inventors: Matthew S. MCLINN, Cincinnati, OH (US); Jared D. WEITZEL, Cincinnati, OH (US); David P. CAMP, II, Florence, KY (US); Scott M. BROWN, Independence, KY (US)

(73) Assignee: GENERAL CABLE TECHNOLOGIES CORPORATION, Highland Heights, KY (US)

(21) Appl. No.: 13/246,183

(22) Filed: Sep. 27, 2011

Related U.S. Application Data
(60) Provisional application No. 61/393,631, filed on Oct. 15, 2010.
(60) Provisional application No. 61/389,984, filed on Oct. 5, 2010.

(51) Int. Cl. H05K 9/00; B82Y 99/00

(52) U.S. Cl. 174/34; 174/388; 174/350; 174/390; 977/734

(57) ABSTRACT

A shielding for a cable component that comprises a base material that is non-conductive and a plurality of conductive particles suspended in or disposed on an outer surface of the base material. The conductive particles are at least one of substantially the same size, the same shape, the same conductive material, different sizes, different shapes, and different conductive materials, such that selection of the conductive particles tunes the frequency bandwidth for effective shielding.

### RELATED APPLICATIONS

This application claims priority under 35 U.S.C. §119 to U.S. Provisional Application Ser. Nos. 61/389,984 and 61/393,631, filed on Oct. 5, 2010 and Oct. 15, 2011, respectively, and both entitled Shielding For Communication Cables Using Conductive Particles, the subject matter of each of which is herein incorporated by reference.

### FIELD OF THE INVENTION

The present invention provides a shielding that uses conductive particles in high concentrations to reduce or eliminate internal and external cable cross talk as well as other EMI/RF from sources outside of the cable. Combinations of conductive particles can be mixed or layered to “tune” the frequency bandwidth at which shielding is effective.

### BACKGROUND OF THE INVENTION

A conventional communication cable typically includes a number of insulated conductors that are twisted together in pairs and surrounded by an outer jacket. Crosstalk or interference often occurs because of electromagnetic coupling between the twisted pairs within the cable or other components in the cable, thereby degrading the cable's electrical performance. Also, as networks become more complex and have a need for higher bandwidth cabling, reduction of cable-to-cable crosstalk (alien crosstalk) becomes increasingly important.

Shielding layers are often used to reduce crosstalk. Conventional shielding layers for communication cables typically include a continuous solid conductive material that is wrapped around the cable's core of twisted wire pairs to isolate electromagnetic radiation from the core and also protect the core from outside interference. The conductive materials that can be used in this arrangement, however, are limited to those specific conductive foils that can be readily vacuum deposited onto flat substrates. Other shielding applications rely on materials that highly absorb and dissipate interference. Shielding formed of such materials, however, are not advantageous in high performance communication cables.

To achieve the higher performance needed for high speed applications, like 40 Gb/s Ethernet cabling, the performance attributes of return loss, insertion loss, internal and external crosstalk must be improved over the conventional 10 Gb/s cabling, and those performance characteristics need to be maintained across a much wider band width. Return loss is a function of the impedance of the individual cable pairs swept across the desired frequency range. The impedance is a function of the size of the conductors in the wire pair, the thickness of the insulation around the conductors in the wire pair, the dielectric constants of the insulations and the distance of the wire pair to the shield. Insertion loss is a measure of the signal attenuation along the cable. Thick foils (typically ranging from 0.0003 to 0.0030 inches in thickness) that are made from aluminum and copper are often employed in conventional cabling to abate return loss and insertion loss. Although thicker foils within the cabling may provide sufficient isolation to control crosstalk, such conventional foils tend to be rigid. Also, during processing, the conventional foils tend to crinkle and crease which changes the impedance along the cable and thus adversely affects return loss. Uniform shielding through the length of the cable enables a more controllable and predictable return loss and impedance. That is because return loss is a measured loss of signal reflected back from the cable due to impedance mis-matching of the device and cable. Also, shield deformation in processing and installation reduces overall return loss performance across the frequency range.

While the conventional shielding materials may reduce the internal cable crosstalk and other EMI from sources outside the pair, such materials do not typically improve return loss, particularly in high speed applications. Moreover, conventional shielding materials have limited application, that is the materials are limited to being applied to only a polymer layer, such as a polyester-backing layer. Therefore, a need exists for a shielding that can be applied to any layer or substrate material while also improving flame and smoke performance even in high performance applications.

### SUMMARY OF THE INVENTION

Accordingly, the present invention provides a shielding for a cable component that comprises a non-conductive base material and a plurality of conductive particles suspended in the base material. The conductive particles may be at least one of substantially the same size, the same shape, the same conductive material, different sizes, different shapes, or different conductive materials, such that selection of the conductive particles tunes the frequency bandwidth for effective shielding.

The present invention also provides a shielding for a cable component that comprises a non-conductive base substrate and a plurality of conductive particles disposed on an outer surface of the base substrate. The conductive particles may be at least one of substantially the same size, the same shape, the same conductive material, different sizes, different shapes, or different conductive materials, such that selection of the conductive particles tunes the frequency bandwidth for effective shielding.

The present invention also provides a cable that comprises a plurality of twisted insulated wire pairs and a shielding surrounding at least one of said wire pairs. The shielding includes a base material that is being non-conductive. A plurality of conductive particles may be suspended in the base material. The conductive particles are at least one of substantially the same size, substantially the same shape, the same conductive material, different sizes, different shapes, or different conductive materials, such that selection of the conductive particles tunes the frequency bandwidth for effective shielding.

Other objects, advantages and salient features of the invention will become apparent from the following detailed description, which, taken in conjunction with the annexed drawings, discloses a preferred embodiment of the present invention.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a partial enlarged view of a shielding according to an exemplary embodiment of the present invention, showing conductive particles suspended in a base material;

FIG. 2 is a partial enlarged view of a shielding according to another exemplary embodiment of the present invention, showing conductive particles suspended in a base material;

FIG. 3 is a partial enlarged view of a shielding according to yet another exemplary embodiment of the present invention, showing conductive particles suspended in a base material;

FIG. 4 is a partial enlarged view of a shielding according to still another exemplary embodiment of the present invention, showing conductive particles settled in a base material;

FIG. 5 is a partial enlarged view of a shielding according to another exemplary embodiment of the present invention, showing a mix of different conductive particles suspended in a base material;

FIG. 6 is a partial enlarged view of a shielding according to yet another exemplary embodiment of the present invention, showing a mix of different conductive particles suspended in a base material;

FIG. 7 is a partial enlarged view of a shielding according to still another exemplary embodiment of the present invention, showing the conductive particles of FIG. 6 settled in the base material;

FIG. 8 is a partial enlarged view of a shielding according to another exemplary embodiment of the present invention, showing conductive particles suspended on a base substrate;

FIG. 9 is a partial enlarged view of a shielding according to still another exemplary embodiment of the present invention, showing a mix of different conductive particles disposed on a base substrate;

FIG. 10 is a partial perspective view of a wire pair of a cable including a shielding segment formed according to the embodiments of the present invention; and

FIG. 11 is a partial perspective view of a shielding according to another embodiment of the present invention, showing conductive particles exhibiting local conductivity and limited general conductivity; and

FIG. 12 is a partial perspective view of a shielding according to yet another embodiment of the present invention, showing high aspect ratio conductive particles exhibiting general conductivity and limited local conductivity.

### DETAILED DESCRIPTION OF THE EXEMPLARY EMBODIMENTS

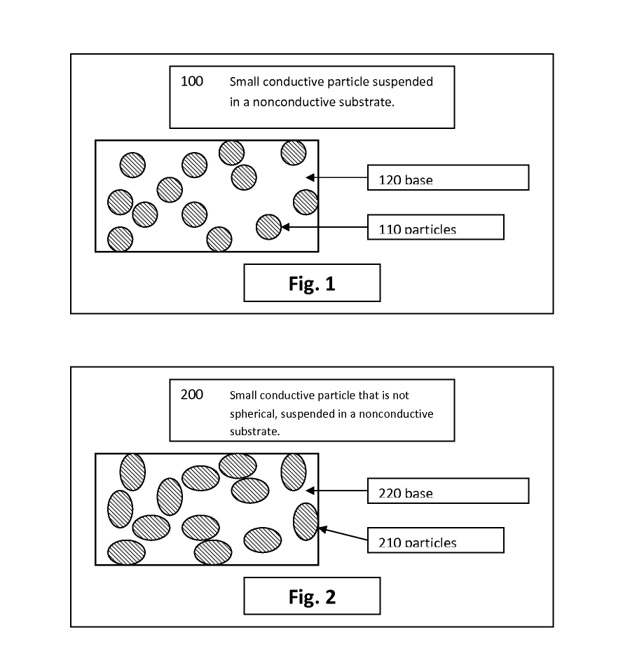

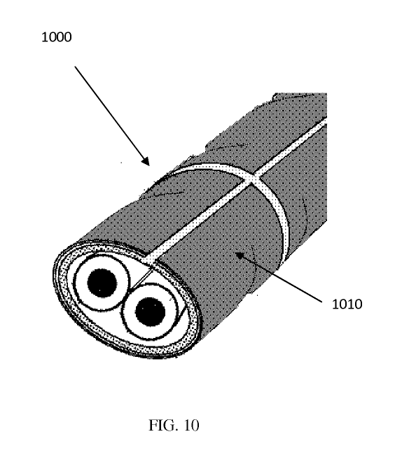

Referring to FIGS. 1-12, a shielding for cable components, such as a wire pair (FIG. 10), according to the exemplary embodiments of the present invention in general uses conductive particles in high concentrations to reduce or eliminate internal and external cable crosstalk as well as other EMI/RF from sources outside of the cable. Combinations of conductive particles that are of different conductive materials, sizes and shapes can by mixed to “tune” the frequency bandwidth of the shielding at which shielding is effective. Tuning of the frequency bandwidth refers to the frequencies at which the shield is effective at providing resistance to electromagnetic radiation. For example, zinc particles can be mixed with a small percentage of silver, usually less than 10%, to improve shielding effectivity without significantly increasing thickness. Another element, such as nickel, which has better electromagnetic permeability for shielding but attenuates the signal, could be used in small percentages with zinc or aluminum.

This tuning can be done because different particles, such as copper, aluminum, zinc, nickel and silver, have varying permeability constants at specific frequencies. In addition, these permeability constants vary differently across various frequency ranges or bandwidth. Particle concentration may also contribute to tuning of the frequency bandwidth by varying the mixture proportions as well as the density of particles through which an electromagnetic wave must propagate. The particles preferably make up about 60%-99% of the shielding. Mixing particles for tuning may refer to more than one type of particle, based on elemental type, size or shape, combined together in a well dispersed manner and in which each type of particle maintains its inherent characteristics on a local or micro scale; however, exhibit inherent characteristics from all of the combined particles on a general scale. Local conductivity refers to conductivity of a small scale region on the order of particle sizes used (e.g. measured in ohm/mm or ohm/mil); whereas, general conductivity refers to conductivity of an area larger than the local conductivity, typically measured in ohm/m or ohm/ft on the maximum allowable installed length of cable per the industry standard requirements. By reducing local conductivity, the localized shielding area becomes more resistive and absorbs more of the interfering energy from outside the shielding layer therefore improving the overall shielding. However, increasing general conductivity of the shielding layer decreases the longitudinal impedance of the shielding layer and causes the signal traveling along the pair or other signal carrying element surrounded by the shielding layer to be less attenuated at higher frequencies, typically greater than 500 MHz.

Alternatively, mixing for tuning may refer to more than one type of particle, based on elemental type, size or shape; combined in distinct regions of like particles in which each type of particle maintains its inherent characteristics on a local scale. This means that the particles are not elementally changed when they are present in the mixture. Every particle type, size, shape and concentration has a specific frequency bandwidth at which it effectively shields to a varying degree across this bandwidth. Thus by increasing the concentration of a specific particle in the shielding, the shielding effectiveness can be increased until a limiting concentration is reached. In addition, multiple layers of each specific mixture could be used to increase shielding.

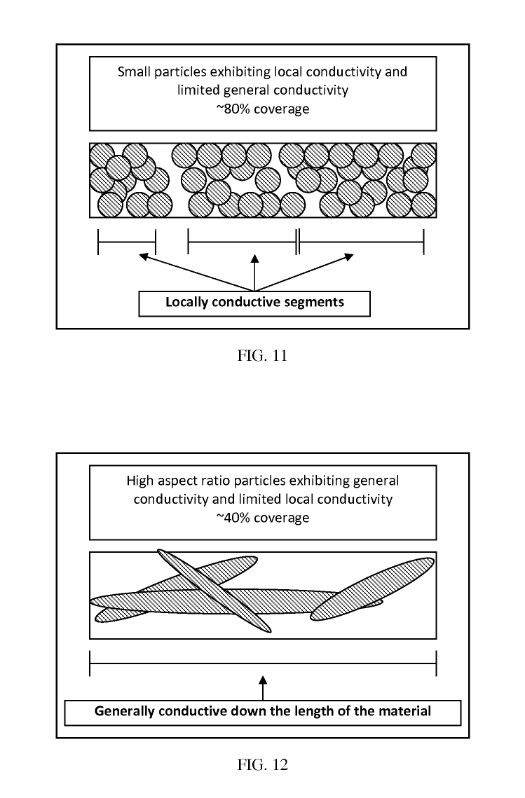

In another example, using smaller particles for tuning allows tighter particle packing, in other words less empty space between particles. This can have the effect of increasing local conductivity. Whereas if high aspect ratio particles are used, general conductivity could increase. Local conductivity is dependent on the coverage area of the particles that exhibit metal like characteristics. Particle size and shape effect local conductivity as smaller particles are able to pack closer together and form a continuous sheet. Particles with a characteristic dimension less than 50 microns are generally considered in this group; however it is highly dependent on the application method if they are able to be placed in close contact. General conductivity is dependent on particle-to-particle contact as larger or high aspect ratio particles are more likely to touch and overlap, but tend to leave larger gaps between the particles. For example, if long rod shaped particles were laid out, there is likely to be conductivity down the length of the shield showing general conductivity; however, if conductivity was measured at a random spot on a small scale, there is a chance that no particles will be touched and exhibit zero local conductivity. This leads to gaps in the shield which would allow the ingress and egress of electromagnetic interference. It would also allow the use of different sized materials to independently adjust or tune the effects that the shield would have on a cable's length-dependant electrical characteristics, such as insertion loss from its cross-sectional-dependant electrical characteristics, such return loss, impedance, near end crosstalk as seen in FIGS. 11 and 12. FIGS. 11 and 12 are examples of small particles that pack well providing good coverage and high aspect ratio particles that might leave gaps but add to overall conductivity down the length of the shield.

By using conductive particles according to the exemplary embodiments of the invention, that are suspended in non-conductive inks or adhesives, for example, the shielding of the present invention may be applied to any substrate or layer material while improving flame and smoke performance over the traditional polyester backing. The shielding of the present invention also has minimal impact on data cable electrical characteristics while still providing adequate shielding.

FIGS. 1-9 illustrate exemplary embodiments of the shielding according to the present invention, showing particle shapes, particle sizes, particle materials and mixture combinations thereof for effective shielding bandwidth. The particles' sizes may range between 0.1-100 microns.

FIG. 1 shows a shielding 100 according to an exemplary embodiment of the invention that includes conductive particles 110 suspended in a non-conductive base material 120. The base material 120 may be, for example, a non-conductive ink or adhesive formed of, for example, an acrylic, enamel or polymer binder, and the like. The conductive particles 110 may have generally the same shape, for example a circular cross-section, and generally the same size. Some particles may be, however, smaller or larger than other particles. The particles may be randomly spaced from another by volume or weight depending on the application method and the standards used in the industry (printing, spraying, etc). The conductive particles 110 may be any conductive material, such as aluminum, copper, iron oxides, nickel, nickel coated graphite, zinc, silver, carbon nano-fibers, or the like. The conductive particles 110 of shielding 100 are preferably formed of the same conductive material; however the particles 110 may be different conductive materials. For example, the conductive particles may be mixtures by volume which typically range from 99% to 70% of aluminum or zinc with a concentration by volume of silver, nickel or nickel coated graphite of between about 1 to 30%. The aluminum particles may be 1-100 microns, for example; the zinc particles may be 1-100 microns, for example; the silver particles may be 0.1-100 microns, for example; the nickel particles may be 1-50 microns, for example; and the nickel coated graphite particles may be 10-200 microns, for example, with the nickel coating ranging from 1% to 50% by volume.

FIG. 2 shows a shielding 200 according to another exemplary embodiment of the invention that is similar to the shielding 100, except that the conductive particles 210 have an oval cross-sectional shape. Like the shielding 100, the conductive particles 210 of the shielding 200 are suspended in a base material 220, are substantially the same size and shape, and may be either the same or different conductive materials.

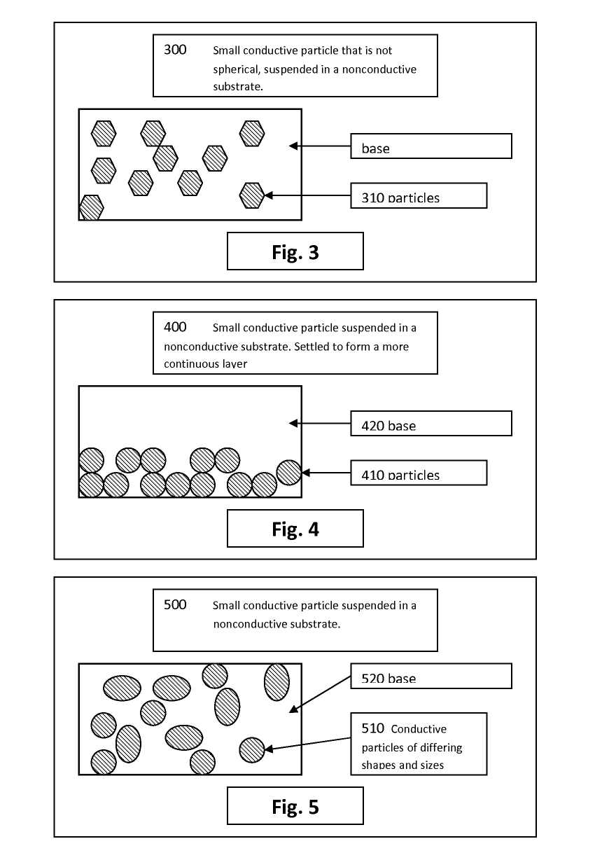

FIG. 3 shows a shielding 300 according to yet another exemplary embodiment of the invention that is similar to the shielding 100 and the shielding 200, except that the conductive particles 310 have a substantially hexagonal cross-sectional shape. The conductive particles 310 preferably have the substantially same size and shape, and may be either the same or different conductive materials like the conductive particles 110 of shielding 100.

FIG. 4. shows a shielding 400 according to still another exemplary embodiment of the invention that includes a base material 420 similar to the base material 120 of the shielding 100 with conductive particles 410. Similar to the conductive particles 110 of the shielding 100, the conductive particles 410 of the shielding 400 have a generally circular cross-sectional shape. The conductive particles 410 are preferably substantially the same size; however some particles may be smaller or larger than others. Unlike the particles of the shielding 100, the conductive particles 410 are settled in the base material 420, thereby forming a more continuous conductive layer for shielding. The conductive particles 410 are preferably formed of the same conductive material, such as aluminum, copper, iron oxides, nickel, nickel coated graphite, zinc, silver, carbon nano-fibers or the like.

FIG. 5 shows a shielding 500 according to another exemplary embodiment of the invention that includes conductive particles 510 suspended in a base material 520 where the conductive particles are preferably a mix of different sizes and shapes. For example, some of the conductive particles may have a generally circular cross-sectional shape and some of the conductive particles may have a generally oval cross-sectional shape, as seen in FIG. 5. The conductive particles 510 are preferably formed of the same conductive material similar to conductive particles 410.

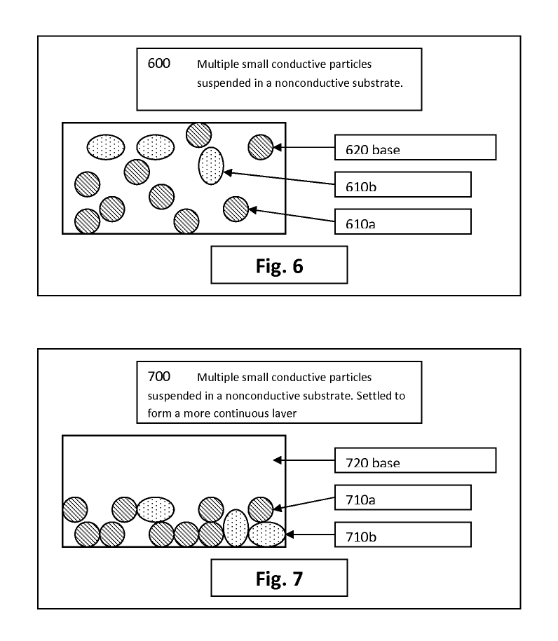

FIG. 6 shows a shielding 600 that is similar to shielding 500, except that the conductive particles are formed of different conductive materials. The conductive materials may be selected from the group of aluminum, copper, iron oxides, nickel, nickel coated graphite, zinc, silver, carbon nano-fibers or the like. For example, some of the conductive particles 610a may have a substantially circular cross-sectional shape and may be formed of the same conductive material. Other conductive particles 610b may, for example, have a substantially oval cross-sectional shape and be formed of a different material than that of the conductive particles 610a.

FIG. 7 shows a shielding 700 according to yet another embodiment of the present invention that includes a base material 720 with conductive particles 710a and 710b. Like the conductive particles 610a and 610b of the shielding 600, the conductive particles 710a and 710b are a mix of sizes, shapes and materials. Unlike the particles of the shielding 600, the conductive particles 710a and 710b are settled in the base material 720 to form a more continuous conductive layer for shielding.

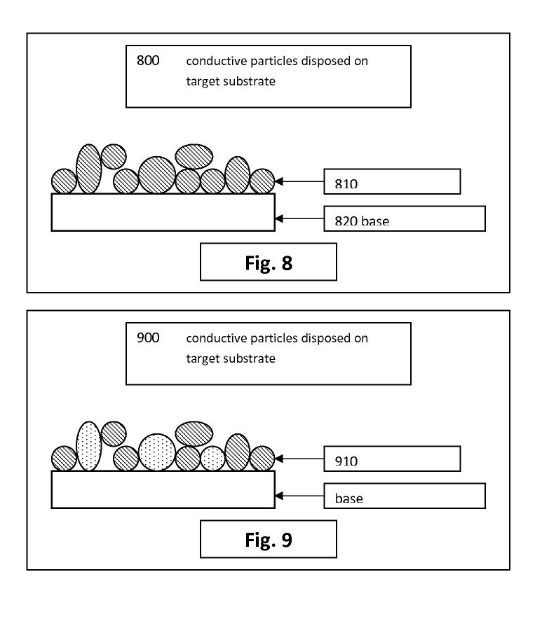

FIG. 8 shows a shielding 800 according to still another embodiment of the present invention that includes a base material or substrate 820 with conductive particles 810 disposed on an outer surface of the substrate 820. The base substrate 820 may be formed of any non-conductive material, such as woven and non-woven textiles including PET, FEP and fiberglass. Preferably the base substrate is a flame retardant material The conductive particles 810 may all have substantially the same size and shape or different sizes as shapes, as seen in FIG. 8. The conductive particles 810 may be formed of the same conductive material, or different conductive materials, as seen in FIG. 9 (showing conductive particles 910 of shielding 900). In both embodiments of FIGS. 8 and 9, the conductive particles may be applied to the base substrate in any known manner, such as by thermally spraying the particles on the substrate.

The shielding of the exemplary embodiments of the present invention may be applied to cable components, such as wire pairs 1000 (FIG. 10), in many different ways including but not limited to the following: spray, wipe on, pressure, electrostatic deposition, chemical deposition and thermal spray techniques. Alternatively, the shielding may be processed to create a shielding segment 1010, as seen in FIG. 10, and as disclosed in co-pending Provisional Application No. 61/390,021 entitled Cable Bather Layer With Shielding Segments, the subject matter of which is herein incorporated by reference. Many different substrates or adhesives can be used as a base material to which the conductive particles are applied.

The amount of particles used can also be decreased if sintering (heating) is used to either increase percent of shielded area or decrease the volume resistivity of the bulk particles once applied. Particle sintering effectively amalgamates the individual particles into a continuous grouping by starting to melt the particles together. By making the particles more continuous, the overall resistance of the particles can be reduced as the shortest path between two particles is reduced. Particle concentration could also remain high and sintering techniques could be applied to even further increase shielding effectiveness. Another way of achieving the same effect is to apply the conductive particles with a thermal application. In this type of system, the conductive particles are heated and applied to the substrate, effectively already semi-sintered together.

While particular embodiments have been chosen to illustrate the invention, it will be understood by those skilled in the art that various changes and modifications can be made therein without departing from the scope of the invention as defined in the appended claims. For example, the conductive particles of the above exemplary embodiments may have any cross-sectional shape, and are not limited to the shapes described herein. Moreover, the shielding of the exemplary embodiments may be applied to any component of a cable.

What is claimed is:

1. A shielding for a cable component, comprising:
a base material, said base material being non-conductive; and
a plurality of conductive particles suspended in said base material, said conductive particles being at least one of substantially the same size, the same shape, the same conductive material, different sizes, different shapes, and different conductive materials, such that selection of said conductive particles tunes the frequency bandwidth for effective shielding.

2. A shielding according to claim 1, wherein
said conductive particles are substantially the same size and substantially the same shape.

3. A shielding according to claim 2, wherein
said conductive particles are formed of the same conductive material.

4. A shielding according to claim 2, wherein
said conductive particles are formed of different conductive materials.

5. A shielding according to claim 1, wherein
said conductive particles are formed of different sizes and shapes.

6. A shielding according to claim 5, wherein
said conductive particles are formed of the same conductive material.

7. A shielding according to claim 5, wherein
said conductive particles are formed of different conductive materials.

8. A shielding according to claim 1, wherein
said conductive particles are selected from the group consisting of aluminum, copper, iron oxides, nickel, zinc, silver or carbon nano-fibers.

9. A shielding according to claim 1, wherein
said base material is an ink or adhesive.

10. A shielding according to claim 1, wherein
said base material is a polymer.

11. A shielding according to claim 1, wherein
said conductive materials are spaced from one another.

12. A shielding according to claim 1, wherein
said conductive materials are settled in said base material such that said conductive particles are in contact with one another.

13. A shielding according to claim 1, wherein
said conductive particles have one of a substantially circular cross-sectional shape, a substantially oval cross-sectional shape, and a substantially hexagonal cross-sectional shape.

14. A shielding according to claim 1, wherein
said conductive particles form at least 80% of the shielding.

15. A shielding according to claim 1, wherein
said base material with said conductive materials suspended therein is applied to the cable component by spraying, wiping on, electrostatic deposition, or chemical deposition.

16. A shielding according to claim 1, wherein
said conductive particles have one of a substantially circular cross-sectional shape, a substantially oval cross-sectional shape, or a substantially hexagonal cross-sectional shape.

17. A shielding according to claim 1, wherein
said conductive particles are a mixture of aluminum or zinc with a concentration by volume of silver, nickel or nickel coated graphite of between 1 to 30%.

18. A shielding according to claim 17, wherein
said aluminum particles are 1-100 microns.

19. A shielding according to claim 17, wherein
said zinc particles are 1-100 microns.

20. A shielding according to claim 17, wherein
said silver particles are 0.1-100 microns.

21. A shielding according to claim 17, wherein
said nickel particles are 1-50 microns.

22. A shielding according to claim 1, wherein
said nickel coated graphite particles are 10-200 microns with the nickel coating ranging from 1% to 50% by volume.

23. A shielding according to claim 1, wherein
said conductive particles are sintered together.

24. A shielding for a cable component, comprising:
a base substrate, said base substrate being non-conductive; and
a plurality of conductive particles disposed on an outer surface of said base substrate, said conductive particles being at least one of substantially the same size, the same shape, the same conductive material, different sizes, different shapes, and different conductive materials, such that selection of the conductive particles tunes the frequency bandwidth for effective shielding.

25. A shielding according to claim 24, wherein
said conductive particles are applied to said base substrate by spraying, wiping on, electrostatic deposition, or chemical deposition.

26. A shielding according to claim 24, wherein
said conductive particles are substantially the same size and substantially the same shape.

27. A shielding according to claim 26, wherein
said conductive particles are formed of the same conductive material.

28. A shielding according to claim 26, wherein
said conductive particles are formed of different conductive materials.

29. A shielding according to claim 26, wherein
said conductive particles are formed of different sizes and shapes.

30. A shielding according to claim 29, wherein
said conductive particles are formed of the same conductive material.

31. A shielding according to claim 29, wherein
said conductive particles are formed of different conductive materials.

32. A shielding according to claim 24, wherein
said conductive particles are selected from the group consisting of aluminum, copper, iron oxides, nickel, zinc, silver or carbon nano-fibers.

33. A shielding according to claim 24, wherein
said conductive particles have one of a substantially circular cross-sectional shape, a substantially oval cross-sectional shape, or a substantially hexagonal cross-sectional shape.

34. A shielding according to claim 24, wherein
said conductive particles are a mixture of aluminum or zinc with a concentration by volume of silver, nickel or nickel coated graphite of between 1 & 30%.

35. A cable, comprising:
a plurality of twisted insulated wire pairs; and
a shielding surrounding at least one of said wire pairs, said shielding including
a base material, said base material being non-conductive, and
a plurality of conductive particles suspended in said base material, said conductive particles being at least one of substantially the same size, the same shape, the same conductive material, different sizes, different shapes, and different conductive materials, such that selection of the conductive particles tunes the frequency bandwidth for effective shielding.
